(19) United States
(12) Patent Application Publication
(10) Pub. No.: US 2019/0067516 A1
(43) Pub. Date: Feb. 28, 2019

(54) SEMICONDUCTOR DEVICE AND MANUFACTURING METHOD THEREOF

(71) Applicant: EPISTAR CORPORATION, Hsinchu (TW)

(72) Inventors: Chun-Hsiang TU, Hsinchu (TW); De-Shan KUO, Hsinchu (TW); Peng-Ren CHEN, Hsinchu (TW)

(21) Appl. No.: 16/118,063

(22) Filed: Aug. 30, 2018

(30) Foreign Application Priority Data
Aug. 31, 2017 (TW) 106129834

(51) Int. Cl. H01L 33/12; H01L 33/18; H01L 33/10; H01L 33/20; H01L 33/32; H01L 33/00

(52) U.S. Cl. CPC H01L 33/12; H01L 33/18; H01L 33/0075; H01L 33/20; H01L 33/32; H01L 33/10

(57) ABSTRACT

The present disclosure provides a semiconductor device including a substrate, a first buffer structure and a semiconductor stack layer. The substrate includes a base part and a plurality of character parts connected to the base part. The first buffer structure is disposed on the base part and is separated from the plurality of character parts by at least one distance. The semiconductor stack layer is disposed on the first buffer structure and the plurality of character parts.

### CROSS REFERENCE TO RELATED APPLICATIONS

This application claims the right of priority based on TW Application Serial No. 106129834, filed on Aug. 31, 2017, and the content of which is hereby incorporated by reference in its entirety.

### FIELD OF DISCLOSURE

The present disclosure relates to a semiconductor device and a manufacturing method thereof, in particular to a semiconductor device having a character part on a substrate and a manufacturing method thereof.

### BACKGROUND OF THE DISCLOSURE

A semiconductor device includes a compound semiconductor composed of III-V group elements, for example, GaP, GaAs, or GaN. A semiconductor device may be an optoelectronic semiconductor device such as a light emitting diode (LED), a laser or a solar cell, or a power device. A structure of an LED includes a p-type semiconductor layer, an n-type semiconductor layer, and an active layer. The active layer is disposed between the p-type semiconductor layer and the n-type semiconductor layer, such that a recombination process of electrons and holes provided by n-type and p-type semiconductor layers respectively occurs in the active layer in an external electric field, so as to convert electrical energy into light energy.

### SUMMARY OF THE DISCLOSURE

The present disclosure provides a semiconductor device including a substrate, a first buffer structure and a semiconductor stack layer. The substrate includes a base part and a plurality of character parts connected to the base part. The first buffer structure is disposed on the base part and is separated from the plurality of character parts by at least one distance. The semiconductor stack layer is disposed on the first buffer structure and the plurality of character parts.

The present disclosure further provides a method for manufacturing a semiconductor device, including providing a substrate which includes a base part and a plurality of character parts connected to the base part, forming a first buffer structure on the substrate to cover the base part, and forming a semiconductor stack layer on the first buffer structure and the plurality of character parts, in which at least a portion of the plurality of character parts is not covered by the first buffer structure.

### BRIEF DESCRIPTION OF THE DRAWINGS

FIG. 1 shows a schematic sectional view of a semiconductor device in accordance with a first embodiment of the present disclosure.

FIG. 2A shows a partially enlarged schematic sectional view of a semiconductor device in accordance with a first embodiment of the present disclosure.

FIG. 2B shows a partially enlarged schematic sectional view of a semiconductor device in accordance with a second embodiment of the present disclosure.

FIG. 3 shows a partial schematic top view of a first buffer structure and a substrate of a semiconductor device in accordance with a first embodiment of the present disclosure.

FIG. 4 shows a partial schematic top view of a first buffer structure and a substrate of a semiconductor device in accordance with a third embodiment of the present disclosure.

FIG. 5 shows a partially enlarged schematic sectional view of a manufacturing process of a semiconductor device in accordance with a first embodiment of the present disclosure.

FIG. 6 shows a partially enlarged schematic sectional view of a semiconductor device in accordance with a first embodiment of the present disclosure.

FIG. 7 shows a partial schematic sectional view of a semiconductor device in accordance with a fourth embodiment of the present disclosure.

FIG. 8 shows a partial schematic top view of a first buffer structure, a second buffer structure and a substrate of a semiconductor device in accordance with a fifth embodiment of the present disclosure.

### DETAILED DESCRIPTION OF THE DISCLOSURE

The following embodiments will be described with accompany drawings to disclose the concept of the present disclosure. In the drawings or description, same or similar portions are indicated with same numerals. Furthermore, a shape or a thickness of a component in the drawings may be enlarged or reduced. Particularly, it should be noted that a component which is not illustrated or described in drawings or description may be in a form that is known by a person skilled in the art.

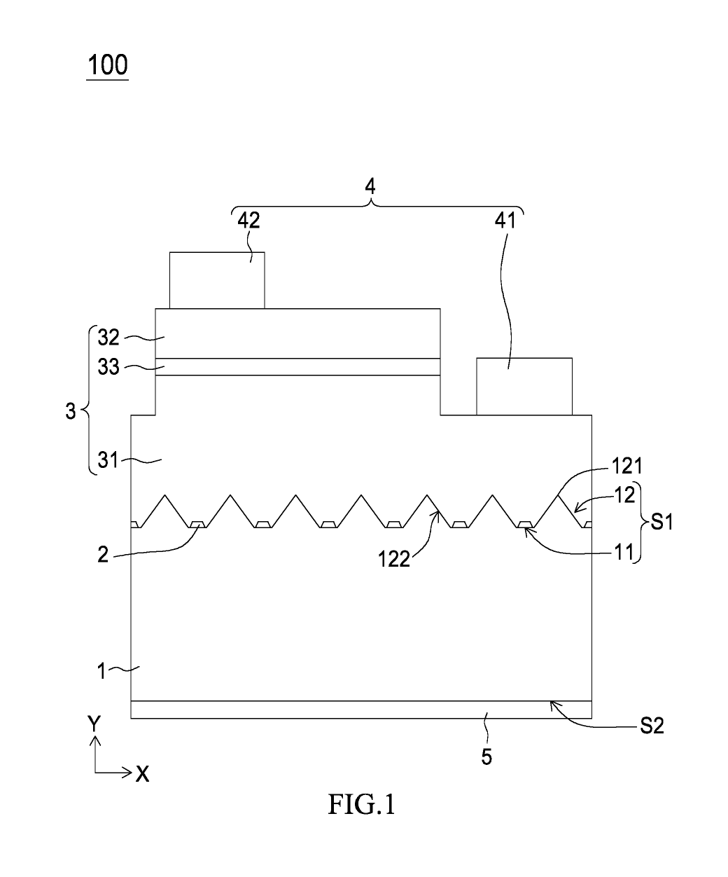

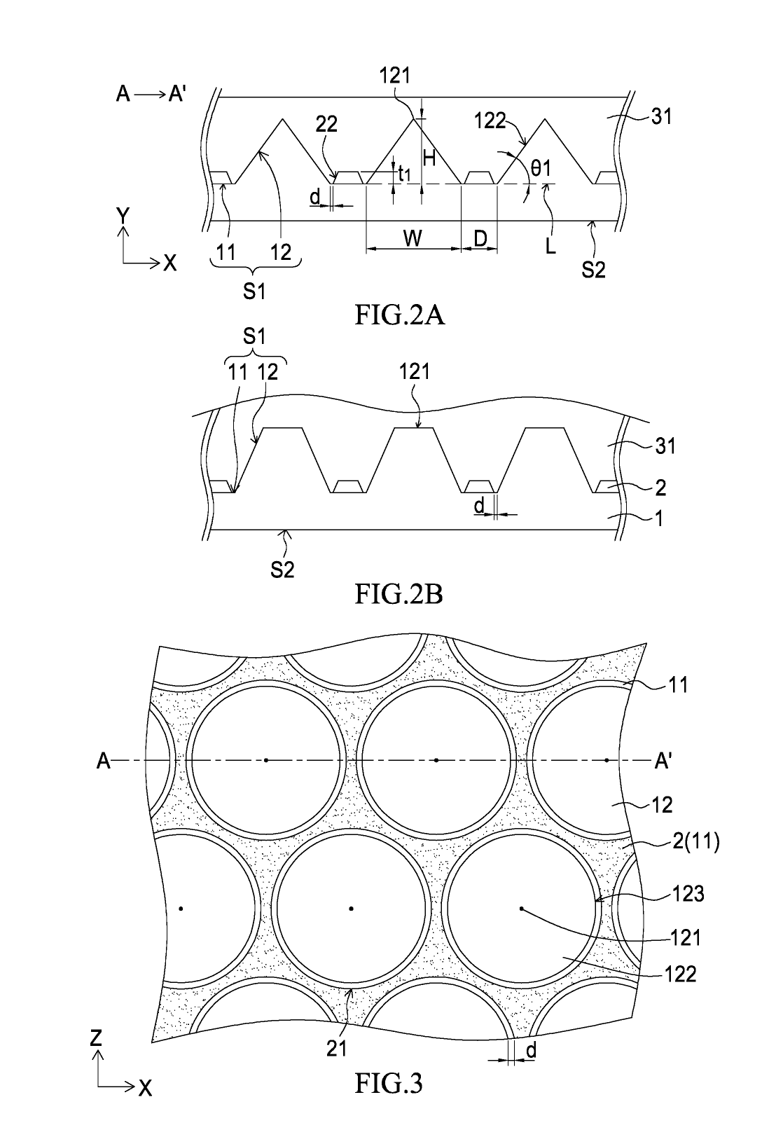

Referring to FIGS. 1 and 2A, a semiconductor device 100 of the first embodiment is a light emitting device such as a light emitting diode or laser. The semiconductor device 100 includes a substrate 1, a first buffer structure 2, and a semiconductor stack layer 3. The first buffer structure 2 is on the substrate 1, and the semiconductor stack layer 3 covers the first buffer structure 2 and the substrate 1. The substrate 1 may support the semiconductor stack layer 3 so as to increase the overall mechanical strength of the semiconductor device 100. Or, the substrate 1 may be used for adjusting a viewing angle of the semiconductor stack layer 3, such that the applicability of the semiconductor device 100 can be extended. However, the function of the substrate 1 is not limited thereto. For example, the substrate 1 may also be used as a growth substrate of the semiconductor stack layer 3. The substrate 1 has a first surface S1 facing the semiconductor stack layer 3 and a second surface S2 opposite to the first surface S1. The second surface S2 is away from the semiconductor stack layer 3. The first surface S1 includes a base part 11 and a plurality of character parts 12 connected to the base part 11, and the plurality of character parts 12 protrudes from or is recessed in the base part 11. Specifically, in the semiconductor device 100 of the first embodiment of the present disclosure, each of the plurality of character parts 12 has an end point 121 from the sectional view. Each end point 121 is farther from the second surface S2 of the substrate 1 than the base part 11 is, so that the character parts 12 protrude relative to the base part 11. Or, in another embodiment, each end point 121 is closer to the second surface S2 of the substrate 1 than the base part 11 is, so that the character parts 12 are recessed relative to the base part 11. The material of substrate 1 may be monocrystalline, polycrystalline, or amorphous. The lattice planes of the base part 11 and the plurality of character parts 12 can be the same or different, and are not limited herein. The substrate 1 of the semiconductor device 100 in the first embodiment is a monocrystalline material, and lattice planes of the base part 11 and the plurality of character parts 12 are respectively different. For example, the material of the substrate 1 of the semiconductor device 100 in the first embodiment is sapphire, the lattice plane of the base part 11 is C-plane of sapphire, and the lattice plane of the plurality of character parts 12 is R-plane of sapphire. In the first embodiment of the present disclosure, a cross-sectional shape of each of the character parts 12 in the substrate 1 is approximately a triangle, but is not limited thereto. For example, the cross-sectional shape of each of the character parts 12 in the substrate 1 may also be approximately arc-shaped, quadrilateral, polygonal or an irregular shape. As shown in FIG. 2B, in the second embodiment, the cross-sectional shape of each of the character parts 12 in the substrate 1 is approximately quadrilateral or trapezoidal. In the present embodiment, the material of the substrate 1 is a single compound and is homogeneously distributed in the whole substrate 1. Specifically, the material compositions at different positions of the substrate 1 are almost the same, such as there are no obvious differences between the elemental composition of the base part 11 and the character parts 12

Referring to FIG. 2A, which shows a partially enlarged schematic sectional view of the semiconductor device 100 in accordance with the first embodiment of the present disclosure. There is a virtual extension line L of the base part 11, which extends toward each of the character parts 12 along the base part 11. The virtual extension line L is under each of the character parts 12, and each of the plurality of character parts 12 has a height H. The height H represents a shortest distance between the end point 121 of each of the character parts 12 and the virtual extension line L of the base part 11. Each of the plurality of character parts 12 has a side surface 122 between the end point 121 and the base part 11, and a first included angle θ1 is defined between the side surface 122 and the virtual extension line L of the base part 11. Furthermore, each of the plurality of character parts 12 has a width W along the virtual extension line L, and there is a spacing D between two adjacent character parts 12. Sizes of the height H, width W and spacing D are about tens of nanometers to tens of micrometers. The height H, width W, spacing D and the first included angle θ1 of each of the plurality of character parts 12 may be the same or different, and are not limited herein. In the first embodiment, the height H of the plurality of character parts 12 is, preferably, about 1 μm to 3 μm, the width W is about 1.5 μm to 5 μm, the spacing D is about 0.05 μm to 2 μm, and the first included angle θ1 is about 30 degrees to 150 degrees or, more preferably, about 50 degrees to 100 degrees. The height H, width W, spacing D and the first included angle θ1 of each of the character parts 12 may be approximately the same. However, the present disclosure is not limited thereto. In the first embodiment, as shown in FIG. 2A, the virtual extension line L of the base part 11 extends along a direction parallel to the X-axis. Or, as shown in FIG. 3, from a top view, the base part 11 has a plane of extension which is parallel to the X-Z plane, and the virtual extension line L may be on the plane of extension and extends toward the character parts 12.

The substrate 1 of the first embodiment may be a transparent substrate, a conductive substrate, a semiconductor substrate or an insulative substrate and is not limited herein. The semiconductor stack layer 3 in the first embodiment may be formed on the substrate 1 or another growth substrate by methods such as metal-organic chemical vapor deposition (MOCVD), molecular-beam epitaxy (MBE) or hydride vapor phase epitaxy (HYPE). If the semiconductor stack layer 3 is formed on a growth substrate, the semiconductor stack layer 3 can be conjugated to the substrate 1 by substrate transfer technology, and the growth substrate may be selectively removed or remained. Moreover, the material of the substrate 1 in the first embodiment may be, but is not limited to, a transparent insulative material such as sapphire, diamond, glass, quartz, acrylic, epoxy, or AN; a transparent conductive oxide (TCO) such as ZnO, ITO, IZO, Ga₂O₃, LiGaO₂, LiAlO₂ or MgAl₂O₄; a semiconductor material such as SiC, GaAs, GaP, GaAsP, ZnSe or InP; or a metallic material such as Al, Cu, Mo, W or a combination of these elements. The substrate 1 of the first embodiment is a growth substrate of the semiconductor stack layer 3, and the plurality of character parts 12 facilitates the growth of the semiconductor stack layer 3 on the substrate 1 and is also capable of reducing the dislocation density of the semiconductor stack layer 3 and elevating the internal quantum efficiency (IQE) in the semiconductor stack layer 3.

Referring to FIGS. 1 and 2A, the first buffer structure 2 is disposed between the substrate 1 and the semiconductor stack layer 3. The first buffer structure 2 covers a portion of the first surface S1 of the substrate 1 and the first buffer structure 2 does not completely cover the first surface S1. Specifically, in the present embodiment, the first buffer structure 2 is only disposed on the base part 11 of the substrate 1, and the first buffer structure 2 is not disposed on the plurality of character parts 12. However, the distribution of the first buffer structure 2 on the first surface S1 is not limited thereto. For example, the first buffer structure 2 may partially cover the first surface S1 of the substrate 1 and expose a portion of the first surface S1 in various shapes from a top view. In addition, as shown in FIGS. 2A and 3, the first buffer structure 2 of the semiconductor device 100 in the first embodiment is located on the base part 11 of the substrate 1, and a distance d is defined between the first buffer structure 2 and one of the plurality of character parts 12. Preferably, the distance d is not less than 10 nm. For example, the distance d is about 10 nm to 200 nm, or is about 50 nm to 100 nm. Referring to FIG. 2A, in this embodiment, the first buffer structure 2 of the semiconductor device 100 has a side wall 22 facing the character parts 12, and the distance d is defined as the distance between the side wall 22 and a character part 12 which is closest to the side wall 22. Specifically, the position where the side wall 22 connected with the base part 11 is defined as one end, and the position where the character part 12 connected with the base part 11 is defined as another end, and the spacing between these two ends is the distance d. In addition, in the first embodiment, the first buffer structure 2 on the base part 11 has a first thickness t1. The first thickness t1 may be about 50 Å to 500 Å, and preferably about 100 Å to 350 Å, such that the epitaxial growth of the subsequent semiconductor stack layer 3 can be of a higher quality through the first buffer structure 2. Compared with the process of performing epitaxial growth in which a buffer layer completely covers the growth substrate, the uniformity in optoelectronic properties of the semiconductor stack layer 3 formed on the substrate 1 may be further improved by partially covering the first surface S1 of the substrate 1 with the first buffer structure 2 as described in the first embodiment, so that different regions of the semiconductor stack layer 3 grown on the substrate 1 may have the same or similar optoelectronic properties. The optoelectronic properties being improved may include dominant wavelength, luminous intensity, luminous flux, color temperature, operating voltage, reverse breakdown voltage, etc. If different positions of the semiconductor stack layer 3 on the same substrate 1 have similar dominant wavelengths and the distribution of wavelengths is narrow, the subsequent sorting process can be simplified and benefit small-sized or miniature LED applications. The first thickness t1 may be an average thickness, the maximum thickness or the minimum thickness of the first buffer structure 2. In the first embodiment, the first thickness t1 is the average thickness of the first buffer structure 2, such as the arithmetic mean of the thicknesses of the first buffer structure 2. In the semiconductor device 100 of the present embodiment, the first thickness t1 extends along a direction parallel to Y-axis in FIG. 2A.

Referring to FIG. 3, which shows a partial schematic top view of the first buffer structure 2 and the substrate 1 of the semiconductor device 100 in accordance with the first embodiment of the present disclosure. The first buffer structure 2 is on the base part 11, and the character parts 12 are exposed as not covered by the first buffer structure 2. From a top view, each of the plurality of character parts 12 has a first profile 123, and the first buffer structure 2 has a plurality of second profiles 21. Each of the second profiles 21 is in outer side of each of the first profile 123 and surrounds the first profile 123. The spacing between each of the first profile 123 and an adjacent second profile 21 is above-mentioned distance d, which is defined between the first buffer structure 2 and one of the plurality of character parts 12. In the present embodiment, each of the first profile 123 is the position where each of the character parts 12 and the base part 11 connect at, and the second profile 21 is the position where the side wall 22 of the first buffer structure 2 and the base part 11 connect at. The first profile 123 and the second profile 21 may be of any shape. For example, in the first embodiment, the first profile 123 of each of the plurality of character parts 12 is approximately a circle, and the first buffer structure 2 is continuously distributed on the base part 11. Accordingly, the first buffer structure 2 is a continuous membrane layer disposed between the plurality of character parts, and the second profile 21 is approximately conformally (conformably) formed outside the first profile 123, but is not limited thereto.

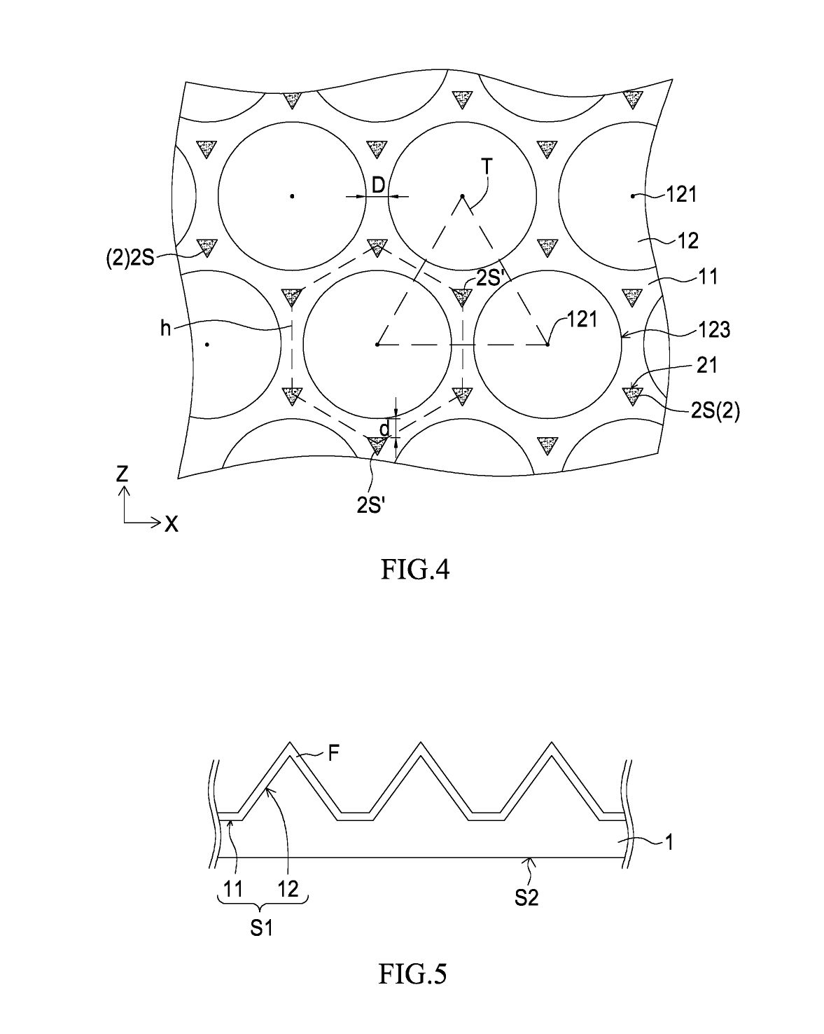

Referring to FIG. 4, in the third embodiment of the present disclosure, the first buffer structure 2 is discontinuously distributed on the base part 11, and the first buffer structure 2 includes a plurality of buffer parts 2S which are separated from each other. From a top view, each of the plurality of character parts 12 has a first profile 123, and each of the buffer parts 2S has a second profile 21. In this embodiment, the distance d is defined as a distance between one of the buffer parts 2S and an adjacent character part 12. The plurality of buffer parts 2S and a portion of the base part 11 are not covered by the first buffer structure 2 or the buffer parts 2S and thus are exposed, in which several buffer parts 2S separated from each other are disposed between the plurality of character parts 12. In one embodiment of the present disclosure, the distribution patterns of the buffer parts 2S and character parts 12 may include several buffer parts 2S encircling one of the character parts 12. For example, multiple buffer parts 2S encircle one of the character parts 12 and the distribution pattern thereof is approximately polygonal-shaped. Or, in another embodiment, the distribution pattern of the buffer parts 2S and the character parts 12 may include several character parts 12 encircling one of the buffer parts 2S. For example, multiple character parts 12 encircle one of the buffer parts 2S and the distribution pattern thereof is approximately polygonal-shaped. The polygonal shape may be a triangular shape, a quadrilateral shape, a pentagonal shape or a hexagonal shape. In the third embodiment, characteristics of distribution of the buffer parts 2S and the character parts 12 from a top view are described as follows: six buffer parts 2S encircle one of the character parts 12, and the distances between an end point 121 of the character part 12 and each of central points 2S′ of the six buffer parts 2S encircling the character part 12 are approximately the same. Imaginary lines between each central point 2S′ and an adjacent central point 2S′ of the six buffer parts 2S approximately form a regular hexagon h which encircles the character part 12. In addition, three character parts 12 encircle one of the buffer parts 2S, and the distances between each end point 121 of the three character parts 12 encircling the buffer part 2S and the central point 2S′ of the buffer parts 2S are approximately the same. Imaginary lines between each end point 121 and an adjacent end point 121 of the three character parts 12 approximately forms a regular triangle T encircling the buffer part 2S. Furthermore, the second profile 21 shown in the third embodiment is approximately a triangle and does not surrounds the first profile 123. In one embodiment, the spacing between the first profile 123 and the second profile 21 is larger than or equal to one half of the spacing D between two adjacent character parts 12. In another embodiment, the second profile 21 is not conformally formed outside the first profile 123, and the spacing between the second profile 21 and the first profile 123 varies in different positions of the semiconductor device 100. In other words, the distance between one of the buffer parts 2S and one side of an adjacent character part 12 is larger, and the distance between one of the buffer parts 2S and another side of the adjacent character part 12 is smaller (not shown). The above-mentioned “conformally” indicates two structures or profiles that have the same or similar patterns are arranged in a relationship that one is larger and the other is smaller, in which the smaller structure or profile is located inside of the larger structure or profile and the larger structure or profile surrounds the smaller structure or profile, and the distances between these two (larger and smaller structures or profiles) are approximately the same.

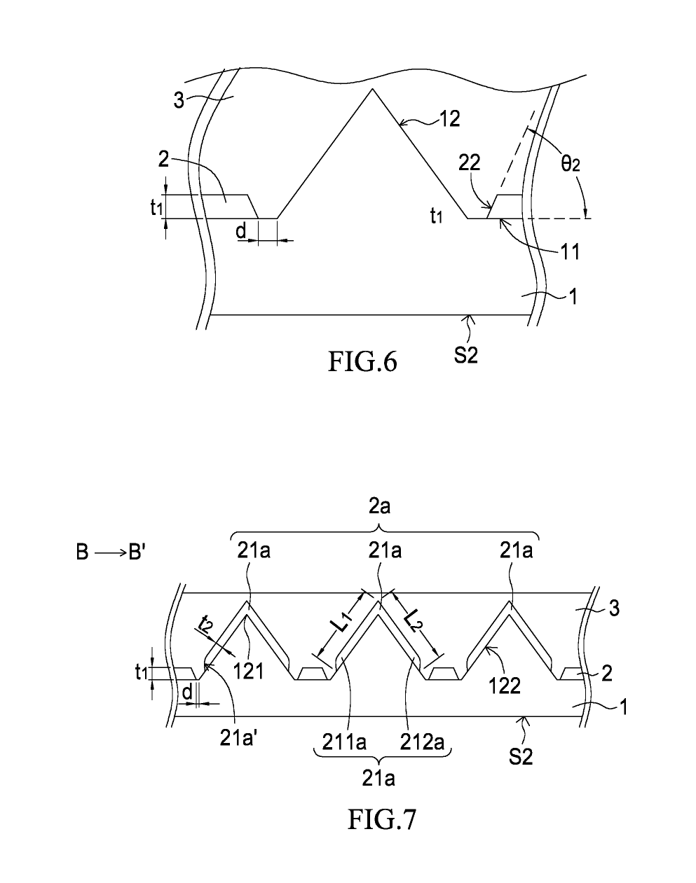

Referring to FIGS. 2A, 3 and 5, the first buffer structure 2 of the first embodiment may be formed by the following steps. First, a continuous buffer structure F is formed on the first surface S1 of the substrate 1, in which the buffer structure F covers the base part 11 and the plurality of character parts 12 at the same time (as shown in FIG. 5). Next, the buffer structure F on the first surface S1 is partially removed, so as to form a patterned first buffer structure 2 which covers a portion of the first surface S1 (as shown in FIGS. 2A and 3). The removal of a portion of the buffer structure F may be performed by wet etching, dry etching or other methods, and is not limited herein. For example, in the present embodiment, the substrate 1 having the buffer structure F may be immersed in an etching solution, such that the buffer structure F on the character parts 12 and the buffer structure F on the base part 11 and close to the character parts 12 are removed by selective etching of the etching solution, and a large portion of the buffer structure F on the base part 11 is retained so as to form the first buffer structure 2 as shown in FIGS. 2A and 3. Or, in another embodiment, formation of the first buffer structure 2 is completed by forming a patterned photoresist on the buffer structure F and removing a portion of the buffer structure F by exposure, development and etching. The etching solution may be selected from alkaline liquids such as KOH, NaOH and NH₃, other acidic or neutral liquids, but is not limited thereto. The material of the photoresist may be selected from poly (p-vinylphenol), polyester acrylate, naphthoquinone diazide derivative, nobolak resin derivative, propylene glycol methyl ether acetate, cyclized polyisoprene, ethyl benzene, xylene, 2-methoxyethyl acetate or other materials. The buffer structure F may be formed on the first surface S1 of the substrate 1 by physical vapor deposition such as sputtering, evaporation deposition, etc., or by methods such as blade coating, and is not limited herein. The buffer structure F and the first buffer structure 2 formed by patterning may include monocrystalline material, polycrystalline material, or amorphous material. In the first embodiment, the material of the buffer structure F and the first buffer structure 2 is a semiconductor monocrystalline material such as GaN, AlN or AlGaN, but is not limited thereto. For example, in another embodiment, the semiconductor stack layer 3 is joined to the substrate 1 by substrate transfer technology, in which a material of the first buffer structure 2 may include a transparent polymeric material, an oxide, a nitride or a fluoride. In addition, in yet another embodiment, the patterned structure of the first buffer structure 2 may be formed not by partially removing the buffer structure F, but by controlling parameters in a manufacturing process (for example, controlling conditions of deposition or coating of the buffer structure F) such that the first buffer structure 2 is formed on a portion of the first surface S1. In other words, the patterned first buffer structure 2 may be formed directly on the first surface S1 without performing an etching process on the buffer structure F. In the first embodiment, crystal planes of the base part 11 and the character parts 12 are different, thus the buffer structure F formed on the base part 11 and on the character parts 12 respectively have different crystallinities. That is, the degree of crystallinity of the buffer structure F on the base part 11 may be different from the degree of crystallinity of the buffer structure F on the character parts 12. For example, the buffer structure F on the base part 11 is monocrystalline and the buffer structure F on the character parts 12 is polycrystalline or amorphous. Accordingly, when conducting a subsequent etching process on the buffer structure F, the buffer structure F on the base part 11 and the buffer structure F on the character parts 12 have different removal rates under the same removal conditions. In the first embodiment, the buffer structure F on the character parts 12 has a lower degree of crystallinity, thus is easier to remove than the buffer structure F on the base part 11. Therefore, the patterned first buffer structure 2 on the base part 11 may be formed directly after an etching process, and it is not necessary to conduct a photolithography process. Furthermore, referring to FIG. 6, in the first embodiment, the side wall 22 of the first buffer structure 2 is facing the character part 12, and a second included angle θ2 is defined between the base part 11 of the substrate 1 and the side wall 22 of the first buffer structure 2, in which the second included angle θ2 is less than 90 degrees. Preferably, the second included angle θ2 is about 10 degrees to 80 degrees, or is about 15 degrees to 50 degrees.

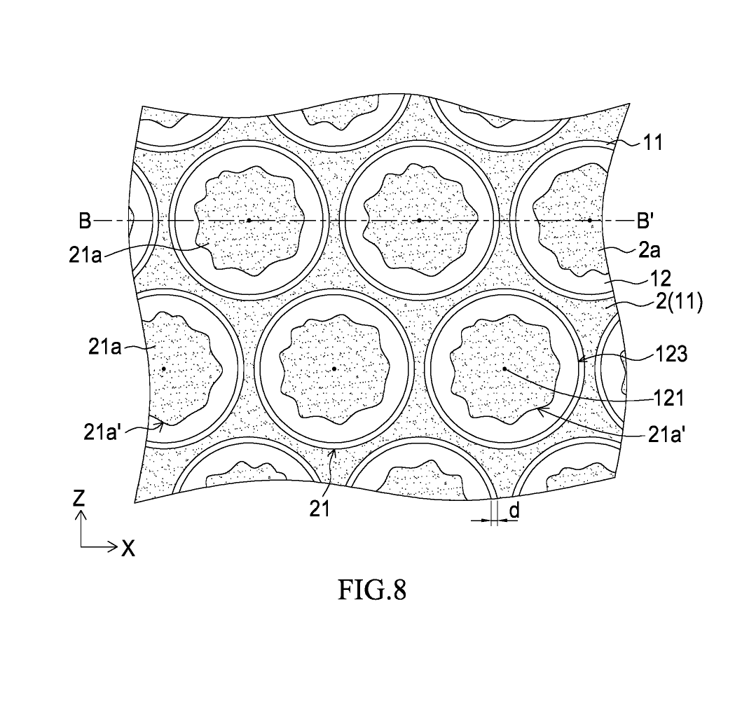

Referring to FIG. 7, which shows a partially enlarged schematic view of the semiconductor device in accordance with a fourth embodiment of the present disclosure. In the semiconductor device of the fourth embodiment, the connection arrangement between each component is similar to that in the semiconductor device 100 of the first embodiment, but is different from that in the semiconductor device of the fourth embodiment because a second buffer structure 2a which disposed on the character parts 12 of the first surface S1 is further included. The materials of the second buffer structure 2a and the first buffer structure 2 may be the same or different. In the fourth embodiment, the material of the second buffer structure 2a is a semiconductor monocrystalline material such as GaN, AlN or AlGaN, and is the same as the material of the first buffer structure 2. To be specific, like the first buffer structure 2, the second buffer structure 2a of the present embodiment is formed by patterning the buffer structure F or formed on the character parts 12 by controlling parameters in a manufacturing process. In the fourth embodiment, the second buffer structure 2a includes a plurality of second buffer parts 21a. Each second buffer part 21a is on each character part 12 of the substrate 1, and is separated from the first buffer structure 2 by a distance which is equal to or larger than the distance d. In other words, as shown in FIG. 7, each of the second buffer parts 21a has a third profile 21a′, and each third profile 21a′ is separated from the side wall 22 of the first buffer structure 2 at a distance not less than the distance d as described in the first embodiment. In addition, the second buffer structure 2a has a second thickness t2. The second thickness t2 and the first thickness t1 of the first buffer structure 2 on the base part 11 may be the same or different, and are not limited herein. However, in the fourth embodiment, the second thickness t2 is preferably less than the first thickness t1 and is in a range of 30 Å to 400 Å or 80 Å to 300 Å. The second thickness t2 may be an average thickness, the maximum thickness or the minimum thickness of the second buffer structure 2a. In the fourth embodiment, the second thickness t2 is the average thickness of the second buffer structure 2a, such as the arithmetic mean of the thicknesses of the second buffer structure 2a, and one of the maximum thickness, the minimum thickness and the average thickness of each second buffer part 21a is approximately equal to the second thickness t2. Furthermore, in a sectional view as shown in FIG. 7, each of the second buffer parts 21a has a first part 211a and a second part 212a, which are disposed on the side surface 122 of the character part 12. The first part 211a has a first length L1, and the second part 212a has a second length L2. The first length L1 and the second length L2 may be the same of different, and are not limited herein. Moreover, referring to FIG. 8 which is a partial schematic top view of the substrate 1, the first buffer structure 2, and the second buffer structure 2a of the fifth embodiment of the present disclosure are disclosed herein. The first buffer structure 2 is on the base part 11 and the second buffer structure 2a is on a portion of the character parts 12. The third profile 21a′ of each of the second buffer parts 21a may be any shape such as approximately a circle or an irregular shape. In the present embodiment, each second profile 21 and first profile 123 encircle each third profile 21a′, and the first profile 123 and the second profile 21 are non-conformally formed beyond the third profile 21a′. The distance between the first profile 123 and the third profile 21a′ is not a constant value, and the distance between the second profile 21 and the third profile 21a′ is also not a constant value. Or, in another embodiment, the second profile 21 conformally encircles the first profile 123, and the first profile 123 conformally encircles the third profile 21a′. In yet another embodiment, the first profile 123, the second profile 21 and the third profile 21a′ are approximately arranged in a shape in which the end point 121 of the character part 12 is at the center.

Referring to FIG. 1, the semiconductor stack layer 3 in the first embodiment is formed on the first buffer structure 2 and the plurality of character parts 12 of the substrate 1. Since the plurality of character parts 12 are not covered by the first buffer structure 2, the semiconductor stack layer 3 and the plurality of character parts 12 are directly connected. Furthermore, the plurality of character parts 12 and a portion of the base part 11 directly contact the semiconductor stack layer 3. Or, as shown in FIG. 7, a portion of the plurality of character parts 12 and a portion of the base part 11 directly contact the semiconductor stack layer 3 in the fourth embodiment. The semiconductor stack layer 3 includes a first semiconductor layer 31, a second semiconductor layer 32 and an active structure 33 disposed between the first semiconductor layer 31 and the second semiconductor layer 32, and the active structure 33 and the second semiconductor layer 32 are formed on the first semiconductor layer 31 in sequence. The first semiconductor layer 31 and the second semiconductor layer 32 respectively have a first conductivity type and a second conductivity type which are different, so as to respectively provide electrons and holes, or holes and electrons. The active structure 33 may include a single heterostructure, a double heterostructure, or multiple quantum wells. The material of the first semiconductor layer 31, the second semiconductor layer 32 and the active structure 33 may be a III-V group compound semiconductor such as GaAs, InGaAs, AlGaAs, AlInGaAs, GaP, InGaP, AlInP, AlGaInP, GaN, InGaN, AlGaN, AlInGaN, AlAsSb, InGaAsP, InGaAsN, or AlGaAsP. In embodiments of the present disclosure, if not described otherwise, above-mentioned chemical formulas include “stoichiometric compounds” and “non-stoichiometric compounds”. A “stoichiometric compound” is a compound in which the total number of atoms of III-group elements is the same as the total number of atoms of V-group elements. On the contrary, a “non-stoichiometric compound” is a compound in which the total number of atoms of III-group elements is different from the total number of atoms of V-group elements. For example, a chemical formula of AlGaAs represents that III-group elements (Al and/or Ga) and a V-group element are included, wherein the total number of atoms of the III-group elements (Al and/or Ga) and the total number of atoms of the V-group elements (As) may be the same or different. In addition, if the above-mentioned compounds represented by the chemical formulas are stoichiometric compounds, then AlGaAs represents for AlₓGa₍₁₋ₓ₎As, wherein 0≤x≤1; AlInP represents for AlₓIn₍₁₋ₓ₎y, wherein 0≤x≤1; AlGaInP represents for (Al_{y}Ga_{(1-y)})₁₋ₓInₓP, wherein 0≤x≤1, and 0≤y≤1; AlGaN represents for AlₓGa₍₁₋ₓ₎N, wherein 0≤x≤1; AlAsSb represents for AlAsₓSb₍₁₋ₓ₎, wherein 0≤x≤1; InGaP represents for InₓGa₁₋ₓP, wherein 0≤x≤1; InGaAsP represents for InₓGa₁₋ₓAs_{1-y}P_{y}, wherein 0≤x≤1, and 0≤y≤1; InGaAsN represents for InₓGa₁₋ₓAs_{1-y}N_{y}, wherein 0≤x≤1, and 0≤y≤1; AlGaAsP represents for AlₓGa₁₋ₓAs_{1-y}P_{y}, wherein 0≤x≤1, and 0≤y≤1; InGaAs represents for InₓGa₁₋ₓAs, wherein 0≤x≤1.

The semiconductor device 100 in the first embodiment of the present disclosure further includes an electrode set 4, thereby introducing an external power source into the semiconductor stack layer 3. The electrode set 4 includes a first electrode 41 electrically connected to the first semiconductor layer 31 and a second electrode 42 electrically connected to the second semiconductor layer 32. The first electrode 41 and the second electrode 42 may be disposed on the same side of the semiconductor stack layer 3, so as to form a horizontal semiconductor device. As shown in FIG. 1, a portion of the second semiconductor layer 32 and a portion of the active structure 33 are removed to expose the first semiconductor layer 31. The first electrode 41 is on the first semiconductor layer 31, and the second electrode 42 is disposed on the second semiconductor layer 32. Or, in another embodiment, the first electrode 41 and the second electrode 42 are respectively disposed on opposite sides of the semiconductor stack layer 3, so as to form a vertical semiconductor device. The material of the electrode set 4 may be Au, Ag, Pt, Cu, Sn, Ni, Ti, or an alloy of above-mentioned metals. In addition, the semiconductor device 100 may further include a reflective layer 5 disposed on the second surface S2 of the substrate 1 for reflecting an emitted light toward the substrate 1 to improve light extraction efficiency. The reflective layer 5 can reflect more than 95% of light back to the semiconductor stack layer 3. In one embodiment, the reflective layer 5 includes a metal mirror. In another embodiment, the reflective layer 5 further includes a distributed Bragg reflector (DBR) disposed between the substrate 1 and the metal mirror, so as to form an omni-directional reflector (ODR). In yet another embodiment, the reflective layer 5 may only include a DBR but not include a metal mirror. The DBR may include low refractive index layers and high refractive index layers that are alternately stacked, in which the low refractive index layers include SiO₂, and the high refractive index layers include AlOₓ or TiO₂. The metal mirror may include Au, Al, Ag, etc.

Another embodiment of the present disclosure is a method for manufacturing a semiconductor device, which includes steps of providing a substrate 1 which includes a base part 11 and a plurality of character parts 12 connected to the base part 11; forming a first buffer structure 2 on the substrate 1 to cover the base part 11 and expose a portion of the plurality of the character parts 12 (that is, a portion of the plurality of the character parts 12 is not covered by the first buffer structure 2); and forming a semiconductor stack layer 3 disposed on the first buffer structure 2 and the plurality of character parts 12. Furthermore, referring to FIGS. 1, 2A and 5, the method for manufacturing a semiconductor device of the present embodiment may include forming a buffer structure F to cover the base part 11 and the plurality of character parts 12, then removing a portion of the buffer structure F to expose a portion of the plurality of character parts 12 and form the first buffer structure 2. Then, the semiconductor stack layer 3 may be formed on the first buffer structure 2 and the plurality of character parts 12. In some embodiments, a distance d is defined between the first buffer structure 2 and each of the plurality of character parts 12, and the distance d is not less than about 10 nm. For example, the distanced is in a range of 10 nm to 150 nm or 50 nm to 100 nm.

It is worth noting that the distribution and thickness of the first buffer structure 2 and/or the second buffer structure 2a on the first surface S1 of the substrate 1 in above-mentioned embodiment may be known by analyzing the structure of the semiconductor device 100. For example, by sectioning the semiconductor device 100 along A-A′ line as shown in FIG. 3, then performing element analysis on positions near the first surface S1 via energy dispersive spectroscopy (EDS), such that the real distributions of the first buffer structure 2 and/or the second buffer structure 2a on the first surface S1 are obtained. To be specific, in the first embodiment, the material of the first buffer structure 2 is AlN, and the material of the semiconductor stack layer 3 that directly connected with the character parts 12 of the substrate 1 is GaN. After the EDS analysis, a signal of Al is found at a position above the base part 11 and there is no signal of Al at a position above the character parts 12, which indicates the first buffer structure 2 is located on the base part 11 and the first buffer structure 2 is not disposed on the character parts 12. In addition, considering the amount of aluminum (Al) can be distinguished in an image of electron diffraction microscopy (a structure containing more amount of aluminum shows a darker color under scanning electron microscopy (SEM), for example), distributions of the first buffer structure 2 and/or the second buffer structure 2a on the first surface S1 can be confirmed by an electron microscopic image of the semiconductor device.

It should be realized that each of the embodiments mentioned in the present disclosure is only used for describing the present disclosure, but not for limiting the scope of the present disclosure. Any obvious modification or alteration is not departing from the spirit and scope of the present disclosure. Same or similar components in different embodiments or components having the same numerals in different embodiments may have same physical or chemical characteristics. Furthermore, above-mentioned embodiments can be combined or substituted under proper condition and are not limited to specific embodiments described above. A connection relationship between a specific component and another component specifically described in an embodiment may also be applied in another embodiment and is within the scope as claimed in the present disclosure.

What is claimed is:

1. A semiconductor device, comprising:
a substrate comprising a base part and a plurality of character parts connected to the base part;
a first buffer structure disposed on the base part and is separated from the plurality of character parts by at least one distance; and
a semiconductor stack layer disposed on the first buffer structure and the plurality of character parts.

2. The semiconductor device of claim 1, wherein the distance is not less than 10 nm.

3. The semiconductor device of claim 1, wherein the first buffer structure comprises a semiconductor monocrystalline material.

4. The semiconductor device of claim 1, wherein the first buffer structure is not disposed on the plurality of character parts.

5. The semiconductor device of claim 1, wherein the semiconductor stack layer is directly connected to the plurality of character parts.

6. The semiconductor device of claim 1, wherein the first buffer structure is a continuous membrane layer and is disposed between the plurality of character parts from a top view.

7. The semiconductor device of claim 1, further comprising a second buffer structure disposed on the plurality of character parts, wherein a thickness of the second buffer structure is less than a thickness of the first buffer structure.

8. The semiconductor device of claim 1, wherein the substrate has a first surface comprising the base part and the plurality of character parts, and lattice planes of the base part and the plurality of character parts are different.

9. The semiconductor device of claim 1, wherein a material of the base part and a material of the plurality of character parts are the same.

10. The semiconductor device of claim 7, wherein a material of the first buffer structure and a material of the second buffer structure are the same.

11. A method for manufacturing a semiconductor device, comprising:
providing a substrate comprising a base part and a plurality of character parts connected to the base part;
forming a buffer structure on the substrate to cover the base part and the plurality of character parts;
partially removing the buffer structure on the plurality of character parts to form a first buffer structure which covers a portion of the base part; and
forming a semiconductor stack layer on the first buffer structure and the plurality of character parts.

12. A semiconductor device as the semiconductor device described in claim 11, wherein a first buffer structure is separated from the plurality of character parts by at least one distance.
